(19) United States
(12) Patent Application Publication
(10) Pub. No.: US 2015/0253277 A1
(43) Pub. Date: Sep. 10, 2015

(54) BIOSENSOR AND MANUFACTURING METHOD THEREOF

(71) Applicant: KABUSHIKI KAISHA TOSHIBA, Tokyo (JP)

(72) Inventors: Makoto WADA, Yokkaichi-Shi (JP); Akihiro KAJITA, Yokkaichi-Shi (JP)

(21) Appl. No.: 14/444,727

(22) Filed: Jul. 28, 2014

Related U.S. Application Data
(60) Provisional application No. 61/949,042, filed on Mar. 6, 2014.

(51) Int. Cl. G01N 27/327; C23C 16/26

(52) U.S. Cl. CPC G01N 27/327; C23C 16/26

(57) ABSTRACT

A biosensor according to one embodiment includes a first electrode, a second electrode, a third electrode, a first insulation layer, and a carbon nanotube electrode. The first, the second, and the third electrode are formed on a substrate and include a same layer. The first insulation layer is formed on the substrate so as to cover the first, the second, and the third electrode. The first insulation layer includes a first opening formed to expose at least a part of a surface of the first electrode, a second opening formed to expose at least a part of a surface of the second electrode, and a third opening formed to expose at least a part of a surface of the third electrode. The carbon nanotube electrode is formed inside of the first opening. A part of the carbon nanotube protrudes from a surface of the first insulation layer.

### CROSS REFERENCE TO RELATED APPLICATION(S)

This application is based upon and claims the benefit of priority from the prior U.S. Provisional Patent Application No. 61/949,042, filed on Mar. 6, 2014, the entire contents of which are incorporated herein by reference.

### FIELD

Embodiments described herein relate generally to a biosensor and manufacturing method thereof.

### BACKGROUND

Biosensors that detect a detection target material by an amperometric measurement method have been known. Generally, amperometric biosensors include a working electrode, a counter electrode, and a reference electrode. Recently, to improve the detection sensitivity, biosensors that include a working electrode formed of a carbon nanotube have been studied. In such biosensors, the material of the working electrode is different from those of other electrodes, and thus there is a problem that a configuration and a manufacturing process of biosensors become complicated.

### BRIEF DESCRIPTION OF THE DRAWINGS

FIG. 1 is a cross-sectional view of an example of a configuration of a biosensor according to an embodiment;

FIGS. 2 to 12 are cross-sectional views of an example of a manufacturing method of a biosensor according to the present embodiment; and

FIG. 13 shows a biosensor including a CNT electrode formed in a fan shape.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a substrate on which electrodes are provided is assumed as “an upper direction”. Therefore, the term “upper direction” or “lower direction” occasionally differs from an upper direction or a lower direction based on a gravitational acceleration direction.

A biosensor according to one embodiment comprises a first electrode, a second electrode, a third electrode, a first insulation layer, and a carbon nanotube electrode. The first electrode, the second electrode, and the third electrode are formed on a substrate and include a same layer. The first insulation layer is formed on the substrate so as to cover the first electrode, the second electrode, and the third electrode. The first insulation layer comprises a first opening formed to expose at least a part of a surface of the first electrode, a second opening formed to expose at least a part of a surface of the second electrode, and a third opening formed to expose at least a part of a surface of the third electrode. The carbon nanotube electrode is formed inside of the first opening. A part of the carbon nanotube protrudes from a surface of the first insulation layer.

### (Configuration of Biosensor)

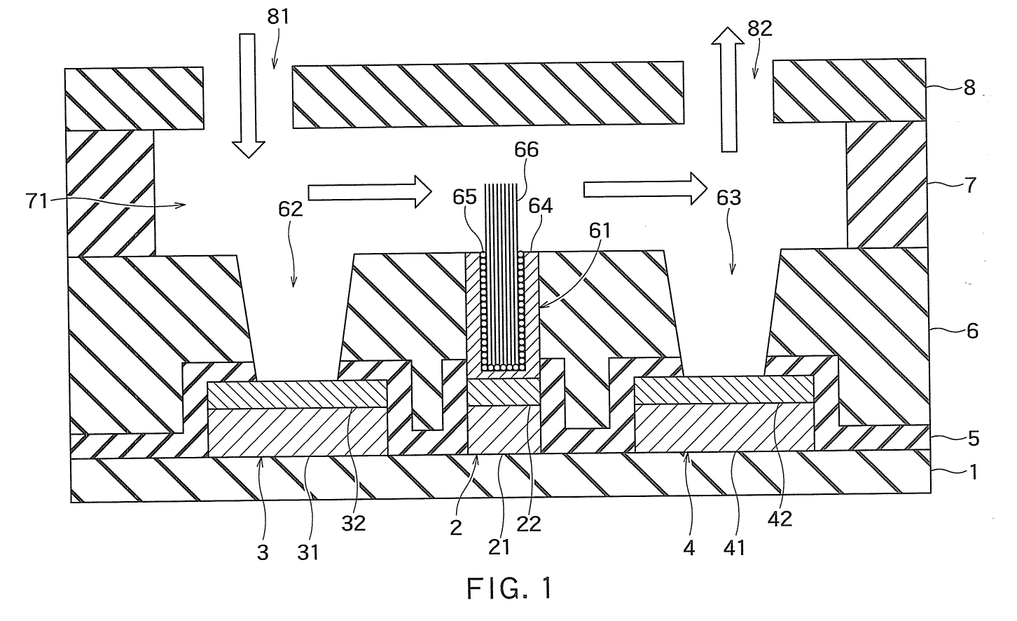

An example of a configuration of the biosensor according to the present embodiment is explained first with reference to FIG. 1. FIG. 1 is a cross-sectional view of the example of the configuration of the biosensor according to the present embodiment. As shown in FIG. 1, the biosensor according to the present embodiment includes a substrate 1, a first electrode 2, a second electrode 3, a third electrode 4, a water prevention layer 5, a first insulation layer 6, a second insulation layer 7, and a cover layer 8.

The substrate 1 is a semiconductor substrate having an insulated surface. Specifically, semiconductor substrates formed of silicon, gallium arsenic, gallium nitride, zinc oxide, indium phosphide, silicon carbide, and the like can be used as the substrate 1. The semiconductor substrates can be insulated by coating an insulator on surfaces thereof.

Further, an insulating substrate formed of an insulator can be also used as the substrate 1. Specifically, insulating substrates formed of silicon oxide, silicon nitride, aluminum oxide, titanium oxide, calcium fluoride, acrylic resin, polyimide, Teflon (registered trademark), and the like can be used as the substrate 1.

The first electrode 2 is a metal electrode formed on the substrate 1. According to the present embodiment, the first electrode 2 is constituted by a base electrode 21 and a surface electrode 22 that are formed of different metal materials. The base electrode 21 is formed on the substrate 1 and the surface electrode 22 is formed on the base electrode 21. That is, the first electrode 2 has a stack configuration of the base electrode 21 and the surface electrode 22. The base electrode 21 and the surface electrode 22 can be formed of arbitrary metal materials.

The base electrode 21 is preferably formed of a metal material more inexpensive than a metal material constituting the surface electrode 22. For example, the base electrode 21 is preferably formed of metal materials such as aluminum, copper, palladium, tantalum, titanium, and compounds thereof.

The surface electrode 22 is preferably formed of a chemically-stable metal material. The surface electrode 22 is preferably formed of metal materials such as platinum, gold, and compounds thereof.

By selecting metal materials constituting the first electrode 2 as explained above, the usage of an expensive metal material such as platinum and gold can be reduced. Accordingly, a biosensor can be manufactured inexpensively.

The first electrode 2 can be formed of a single metal material. In this case, the first electrode 2 is preferably formed of a metal material similar to that of the surface electrode 22. The first electrode 2 can have a stack configuration of three layers or more. In any case, the top layer of the first electrode 2 is preferably formed of a chemically-stable metal material.

Similarly to the first electrode 2, the second electrode 3 and the third electrode 4 are metal electrodes formed on the substrate 1. The second electrode 3 and the third electrode 4 are formed so as to include the same layer as the first electrode 2. That is, surfaces of the first electrode 2, the second electrode 3, and the third electrode 4 are formed so as to be on the same plane.

The second electrode 3 and the third electrode 4 have a configuration similar to that of the first electrode 2. According to the present embodiment, the second electrode 3 has a stack configuration of a base electrode 31 and a surface electrode 32. Similarly, the third electrode 4 has a stack configuration of a base electrode 41 and a surface electrode 42.

The first electrode 2, the second electrode 3, and the third electrode 4 are formed of an identical metal material. This means that when the respective electrodes have a stack configuration, metal materials of the respective corresponding layers are identical to one another. Therefore, according to the present embodiment, the base electrodes 21, 31, and 41 are formed of an identical metal material. The surface electrodes 22, 32, and 42 are also formed of an identical metal material.

In the biosensor according to the present embodiment, one of the second electrode 3 and the third electrode 4 is used as a counter electrode and the other is used as a reference electrode. While the second electrode 3 is used as the counter electrode and the third electrode 4 is used as the reference electrode below for convenience, the opposite is also true. When a detection target material is to be detected by the biosensor according to the present embodiment, at least some parts of surfaces of the second electrode 3 and the third electrode 4 are exposed to a solvent containing the detection target material. Therefore, the surface electrodes 32 and 42 are formed of a chemically-stable metal material, so that a counter electrode and a reference electrode with high corrosion resistance can be formed.

The water prevention layer 5 is formed so as to cover the entire surface of the substrate 1 and expose at least some parts of the surfaces of the first electrode 2, the second electrode 3, and the third electrode 4. The water prevention layer 5 is formed to prevent water from entering the substrate 1. As a result, the substrate 1 can be protected from water. When an electronic circuit (a signal processing circuit) is formed in the substrate 1, the electronic circuit can be protected by the water prevention layer 5.

The water prevention layer 5 is formed of an insulator so that the first electrode 2, the second electrode 3, and the third electrode 4 are not short-circuited. The water prevention layer 5 can be formed of an arbitrary insulator mentioned above. The water prevention layer 5 is preferably formed of silicon nitride. A configuration in which a biosensor does not include the water prevention layer 5 can be also employed.

The first insulation layer 6 is formed on the water prevention layer 5. When a biosensor does not include the water prevention layer 5, the first insulation layer 6 is formed directly on the substrate 1. The first insulation layer 6 can be formed of an arbitrary insulator mentioned above. For example, the first insulation layer 6 is formed of silicon oxide, silicon nitride, and the like. The first insulation layer 6 includes a first opening 61, a second opening 62, and a third opening 63.

The second opening 62 is formed so that at least a part of the surface of the second electrode 3 is exposed. The part of the second electrode 3 exposed from the second opening 62 contacts a solvent. The second electrode 3 can thus function as a counter electrode.

The third opening 63 is formed so that at least a part of the surface of the third electrode 4 is exposed. The part of the third electrode 4 exposed from the third opening 63 contacts a solvent. The third electrode 4 can thus function as a reference electrode.

The first opening 61 is formed so that at least a part of the surface of the first electrode 2 is exposed. An underlayer 64, a catalyst layer 65, and a carbon nanotube electrode 66 are formed inside of the first opening 61. The underlayer 64 is formed so as to cover an inner surface of the first opening 61. The underlayer 64 is formed of promoter metal. The promoter metal is a metal material that facilitates growth of a carbon nanotube (hereinafter, “CNT”) from the catalyst layer 65. Titanium nitride is preferably used as the promoter metal. A configuration in which a biosensor does not include the underlayer 64 can be also employed.

The catalyst layer 65 is formed so as to cover an inner surface of the underlayer 64. The catalyst layer 65 is formed of catalyst metal for growing a carbon nanotube. Cobalt, nickel, iron, and the like are preferably used as the catalyst metal. The CNT can thus be selectively grown from the inside of the first opening 61.

The carbon nanotube electrode (hereinafter, “CNT electrode”) 66 is formed inside of the catalyst layer 65. The CNT electrode 66 functions as a working electrode of a biosensor. The CNT electrode 66 is electrically connected to the first electrode 2 via the catalyst layer 65 and the underlayer 64 formed of a metal material.

The CNT electrode 66 is formed of a plurality of CNTs grown from the catalyst layer 65. A SW (Single Wall) CNT, a DW (Double Wall) CNT, and a MW (Multi Wall) CNT can be used as a CNT constituting the CNT electrode 66.

Because the CNT electrode 66 is formed of a CNT, the CNT electrode 66 has high sensitivity of detecting a detection target material and is advantageous, for example, in detecting a detection target material containing an aromatic compound. According to the present embodiment, a part of the CNT electrode 66 protrudes from the surface of the first insulation layer 6. Therefore, the CNT electrode 66 has a large surface area contacting a detection target material. By using such CNT electrode 66 as a working electrode, the detection sensitivity of a biosensor can be further improved.

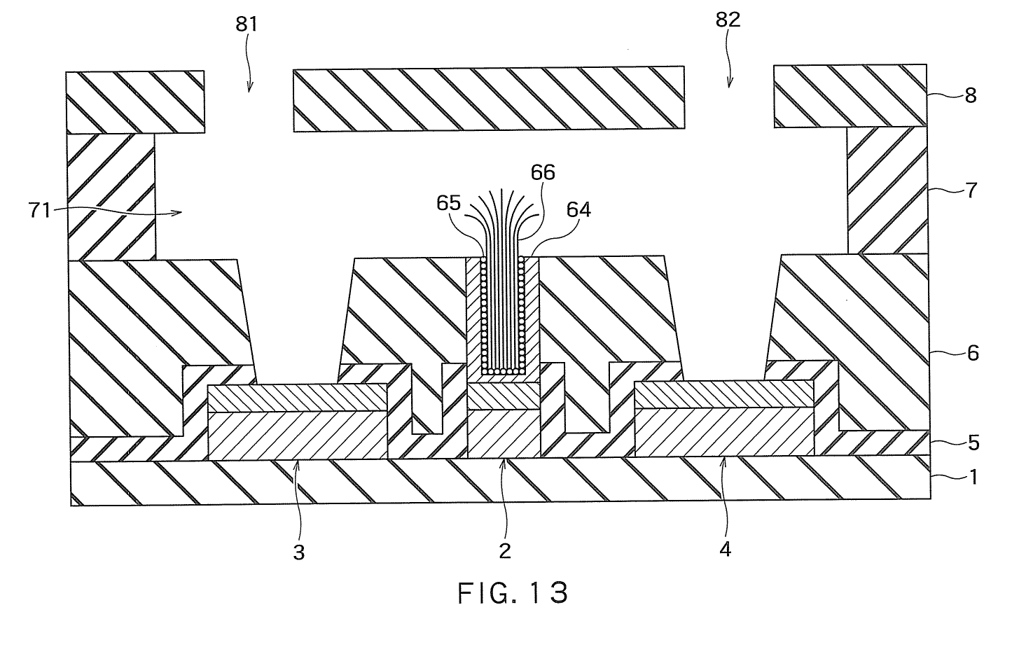

The protruded part of the CNT electrode 66 can be formed linearly as shown in FIG. 1 or can be formed so as to spread from the surface of the first insulation layer 6 in a fan shape as shown in FIG. 13. The protruded part of the CNT electrode 66 is formed in a fan shape, so that the surface area of the CNT electrode 66 can be further increased. The biosensor according to the present embodiment detects an interaction between a specific material immobilized on the CNT electrode 66 and a detection target material in a solvent as a change in a voltage or a current. The specific material is an arbitrary material that selectively interacts with a detection target material of a biosensor. The specific material can be immobilized on the CNT electrode 66 by an arbitrary method. For example, the specific material can be immobilized by impregnating the CNT electrode 66 into a solvent containing the specific material.

Examples of a detection target material and a specific material include protein (enzyme, antigen, antibody, lectin, and the like), peptide, lipid, hormone (nitrogen-containing hormone made of amine, amino-acid derivative, peptide, protein, and the like and steroid hormone), nucleic acid, sugar, oligosaccharide, polysaccharide chain, pigment, low-molecular compound, organic material, inorganic material, pH, ion (Na⁺, K⁺, Cl⁻, and the like), virus, molecule constituting cell, and blood cell.

Examples of an interaction between a detection target material and a specific material include covalent bond, coordinate bond, dipole bond, hydrophobic bond, hydrogen bond, van der Waals bond, and electrostatic bond. The interaction also includes binding reaction, synthesis reaction, and decomposition reaction as a result of the interactions mentioned above. Moreover, the interaction includes a change in the external environment such as pH, ion, temperature, pressure, dielectric constant, resistance value, and viscosity as a result of the reactions of the detection target material and the specific material mentioned above.

Specific examples of the interaction mentioned above include binding and dissociation of antigen and antibody, binding and dissociation of protein receptor and ligand, binding and dissociation of adhesion molecule and adhered molecule, binding and dissociation of enzyme and substrate, binding and dissociation of apoenzyme and coenzyme, binding and dissociation of nucleic acid and protein, binding and dissociation of glycoprotein and protein, binding and dissociation of sugar chain and protein, binding and dissociation of cell and biotissue to and from protein, binding and dissociation of cell and biotissue to and from low-molecular compound, and interaction of ion and ion-sensitive material.

A specific material need not be immobilized on the CNT electrode 66. In this case, it suffices that a user of a biosensor immobilizes a specific material according to a desired detection target material on the CNT electrode 66.

The second insulation layer 7 is formed on a part of the first insulation layer 6. The material of the second insulation layer 7 is an arbitrary insulator such as silicon oxide and silicon nitride, and can be identical to an insulator constituting the first insulation layer 6 or be different therefrom. A trench 71 is an area where the second insulation layer 7 is not formed on the first insulation layer 6. The trench 71 is formed so as to be spatially continuous with the openings 61, 62, and 63. Therefore, the second insulation layer 7 is formed on an outer edge of a biosensor and serves as a sidewall of the trench 71.

The cover layer 8 is formed on the second insulation layer 7 so as to cover the top of the first insulation layer 6. That is, the cover layer 8 serves as a cover that covers the trench 71. The cover layer 8 is formed of an insulator such as silicon oxide and silicon nitride. For example, the cover layer 8 is preferably formed of silicon nitride.

A first through hole 81 and a second through hole 82 are formed in the cover layer 8. The first through hole 81 and the second through hole 82 are an opening that passes from the top surface to the bottom surface of the cover layer 8. The first through hole 81 and the second through hole 82 are formed on the trench 71. Three through holes or more can be formed in the cover layer 8.

The first through hole 81 and the second through hole 82 are formed to constitute a flow path. The flow path is constituted by the second opening 62, the third opening 63, the trench 71, the first through hole 81, and the second through hole 82. The first through hole 81 and the second through hole 82 serve as an entrance and an exit of the flow path. While explanations are given below assuming that the first through hole 81 is the entrance and the second through hole 82 is the exit, the opposite is also true.

According to the biosensor of the present embodiment, a solvent containing a detection target material flows in the flow path explained above. That is, the solvent flows in through the first through hole 81, contacts the second electrode 3 (the counter electrode), the CNT electrode 66 (the working electrode), and the third electrode 4 (the reference electrode) in the flow path, and flows out through the second through hole 82. Arrows in FIG. 1 denote the flow of the solvent. The biosensor detects the detection target material contained in the solvent flowing in the flow path.

The third electrode 4 (the reference electrode) sets an input impedance high and applies a standard electrode potential. The CNT electrode 66 (the working electrode) reacts with the detection target material, thereby causing a change in a current between the CNT electrode 66 (the working electrode) and the second electrode 3 (the counter electrode). By sensing this change, the detection target material can be detected. Because the CNT electrode 66 serving as a working electrode has high sensitivity of detecting the detection target material and the electric resistivity of the CNT itself is low, the CNT electrode 66 can function as a highly sensitive biosensor and detect a material with high sensitivity and high selectivity. Therefore, the time for inspection can be also reduced. When a signal processing circuit is included in the substrate 1, the second electrode 3 (the counter electrode), the CNT electrode 66 (the working electrode), and the third electrode 4 (the reference electrode) are connected to the signal processing circuit in the substrate 1. Examples of the signal processing circuit include a sensing circuit that monitors a current value and a booster circuit that applies a voltage.

According to the present embodiment, a part of the CNT electrode 66 protrudes from the surface of the first insulation layer 6. The trench 71 is formed so as to cover the top of the first opening 61. A part of the CNT electrode 66 thus protrudes within the trench 71. For this reason, the CNT electrode 66 can contact a solvent flowing in the trench 71 successfully. With such a configuration, the detection sensitivity of a biosensor can be improved.

Because the biosensor according to the present embodiment is formed so that the first electrode 2, the second electrode 3, and the third electrode 4 include the same layer, in a manufacturing process to be explained later, these three electrodes can be formed simultaneously. As a result, the manufacturing process can be simplified.

The biosensor according to the present embodiment can be formed in plural on the single substrate 1. The biosensor can also include the first electrode 2, the second electrode 3, the third electrode 4, and the CNT electrode 66 in plural. Further, the arrangement order of the first electrode 2, the second electrode 3, and the third electrode 4 can be selected arbitrarily.

According to the biosensor of the present embodiment, a configuration in which the second insulation layer 7 and the cover layer 8 are not provided can be employed. In this case, the biosensor can be put or installed and used in a container such as a beaker having a solvent stored therein. Alternatively, the biosensor can be installed and used on a flow path of a solvent that is formed outside.

The substrate 1 can include a signal processing circuit that performs a process of detecting a detection target material based on electrical signals obtained from the first electrode 2, the second electrode 3, and the third electrode 4. In this case, the substrate 1 is preferably formed of a semiconductor substrate. It suffices that the signal processing circuit is formed by an existing manufacturing process of a semiconductor element.

Further, the substrate 1 can include a wire and a terminal (both not shown in FIG. 1) electrically connected to the first electrode 2, the second electrode 3, and the third electrode 4. With such a configuration, a biosensor can output electrical signals obtained from the first electrode 2 (the CNT electrode 66), the second electrode 3, and the third electrode 4 via the terminal to an external device. The external device can perform a process of detecting a detection target material based on the obtained electrical signals.

### (Manufacturing Method of Biosensor)

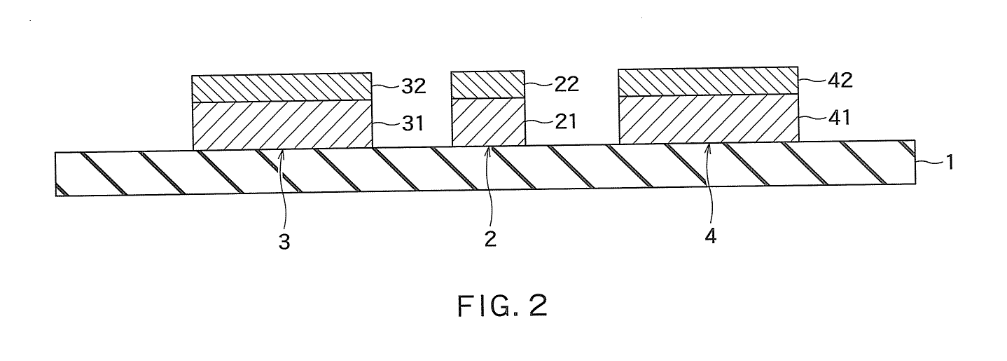

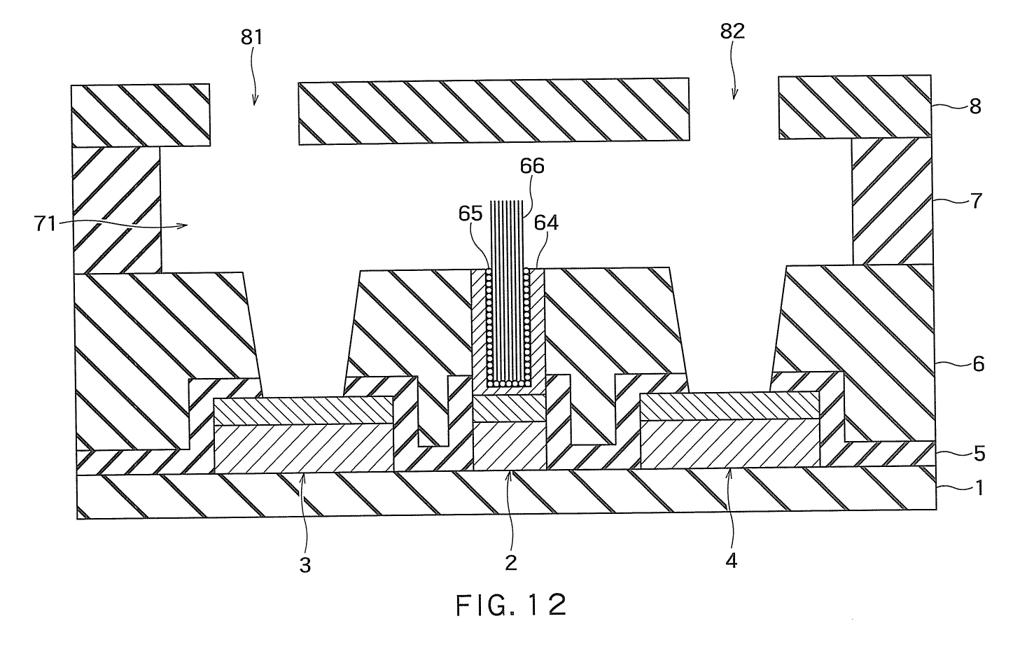

A manufacturing method of a biosensor according to the present embodiment is explained next with reference to FIGS. 2 to 12. FIGS. 2 to 12 are cross-sectional views of an example of the manufacturing method of a biosensor according to the present embodiment. A stacking method employed at a stacking step to be explained below is selected depending on a stacked material and the thickness of a layer. As the stacking method, CVD (Chemical Vapor Deposition), PVD (Physical Vapor Deposition), plating, and the like are included.

A first metal material layer is stacked first on the substrate 1. The first metal material layer is formed by stacking a metal material constituting the base electrodes 21, 31, and 41. Next, a second metal material layer is stacked on the first metal material layer. The second metal material layer is formed by stacking a metal material constituting the surface electrodes 22, 32, and 42.

Next, a part of the stacked first and second metal material layers is removed by lithography and etching (such as RIE (Reactive Ion Etching)). As a result, as shown in FIG. 2, the first electrode 2, the second electrode 3, and the third electrode 4 each of which includes a base electrode and a surface electrode are formed. Because the first electrode 2, the second electrode 3, and the third electrode 4 are formed by removing a part of a common metal material layer, the electrodes are formed so as to include the same layer. When the first electrode 2, the second electrode 3, and the third electrode 4 have a single layer configuration or a stack configuration of three layers or more, it suffices that the stacking step described above is repeated for the number of times equal to the number of layers to be stacked, and then a formed stack configuration is processed by lithography and etching. In this manner, the first electrode 2, the second electrode 3, and the third electrode 4 can be formed simultaneously.

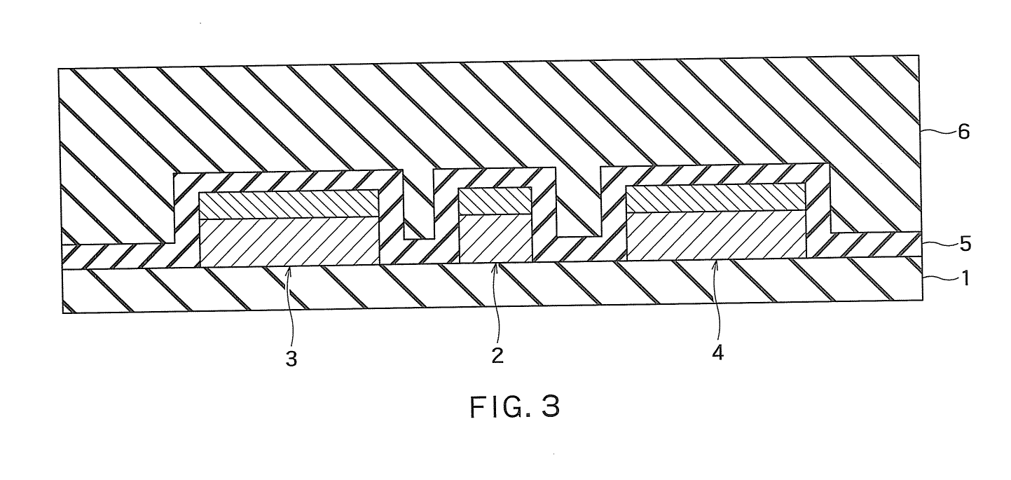

Next, the water prevention layer 5 is stacked on the substrate 1 and the first insulation layer 6 is stacked on the water prevention layer 5. FIG. 3 is a cross-sectional view of a state where the first insulation layer 6 is stacked on the water prevention layer 5. When a biosensor does not include the water prevention layer 5, a step of stacking the water prevention layer 5 can be omitted. In this case, the first insulation layer 6 is stacked directly on the substrate 1.

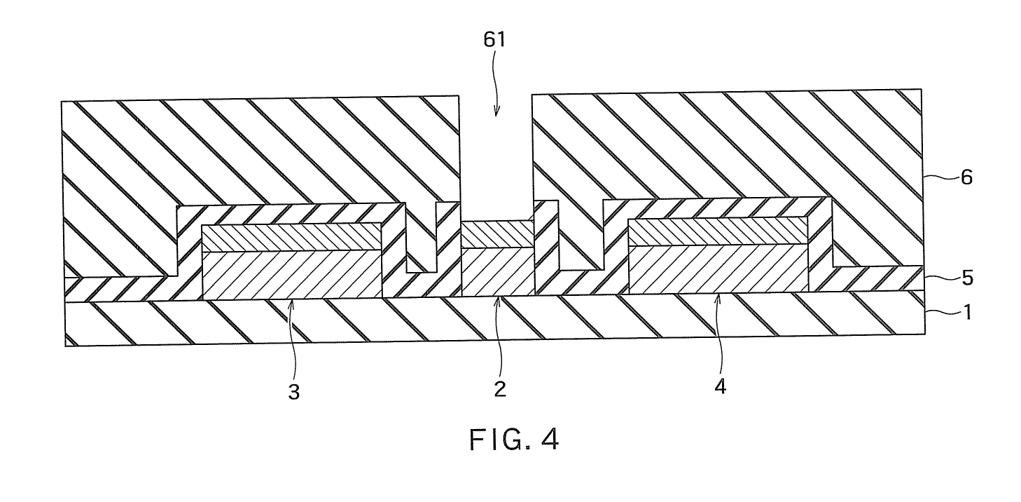

Next, as shown in FIG. 4, the first opening 61 is formed by lithography and etching. The first opening 61 is formed so that at least a part of a surface of the first electrode 2 (the surface electrode 22) is exposed.

Next, the underlayer 64 is stacked so as to cover a surface of the first insulation layer 6 and an inner surface of the first opening 61. That is, the underlayer 64 is stacked so as not to fill the inside of the first opening 61. Similarly, the catalyst layer 65 is stacked so as to cover a surface of the underlayer 64 and the inner surface of the first opening 61. That is, the catalyst layer 65 is stacked so as not to fill the inside of the first opening 61. When a biosensor does not include the underlayer 64, a step of stacking the underlayer 64 can be omitted. In this case, the catalyst layer 65 is stacked directly on the surface of the first insulation layer 6 and the inner surface of the first opening 61.

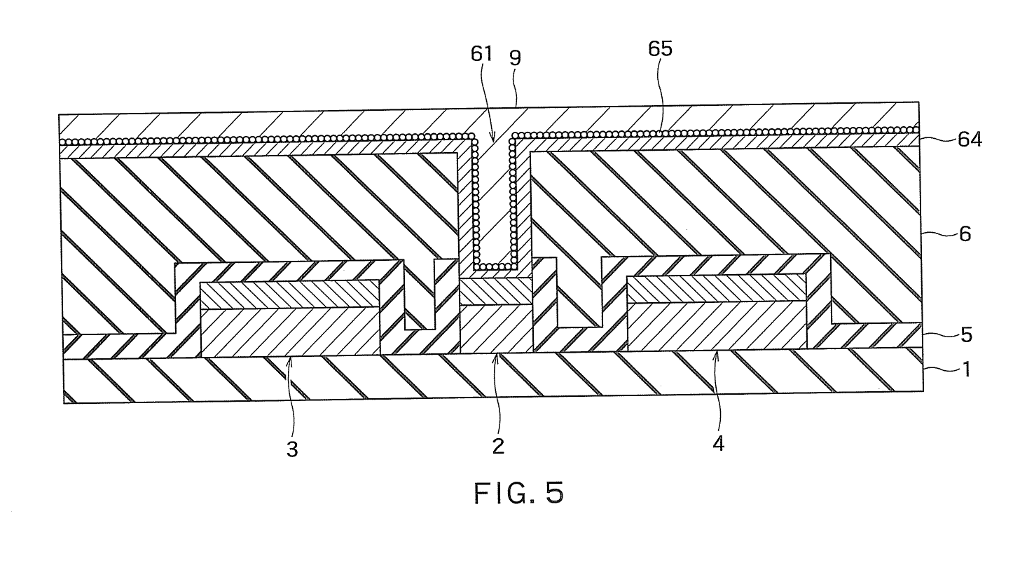

Further, a first sacrificial layer 9 is stacked on the catalyst layer 65. FIG. 5 is a cross-sectional view of a state where the first sacrificial layer 9 is stacked. As shown in FIG. 5, the first sacrificial layer 9 is stacked so as to fill the inside of the first opening 61. The first sacrificial layer 9 is stacked assuming that it is removed at a subsequent step. A resist material containing carbon is stacked as the first sacrificial layer 9. For example, the first sacrificial layer 9 can be stacked by spin coating.

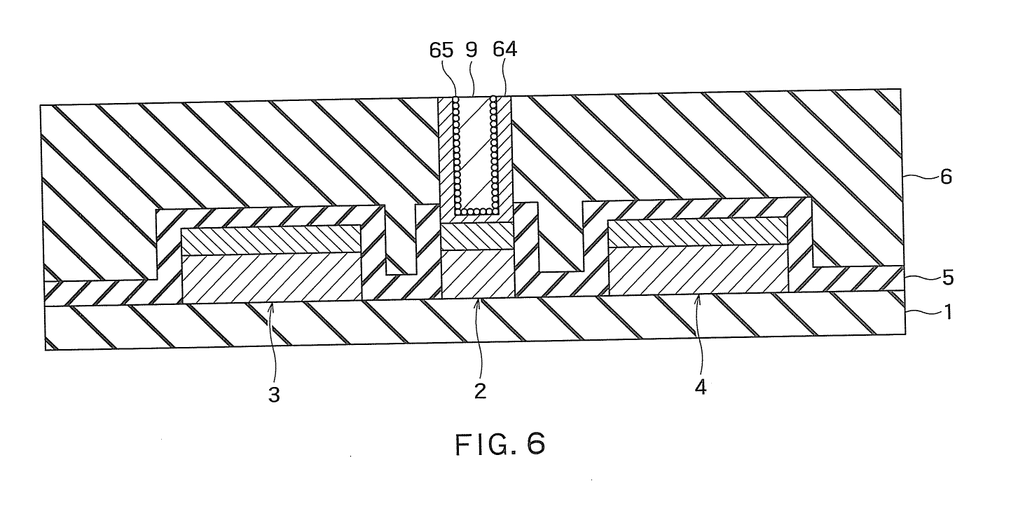

Next, the first sacrificial layer 9, the catalyst layer 65, and the underlayer 64 are removed by CMP (Chemical Mechanical Polishing) until the surface of the first insulation layer 6 is exposed. FIG. 6 is a cross-sectional view of a state where the surface of the first insulation layer 6 is exposed by CMP.

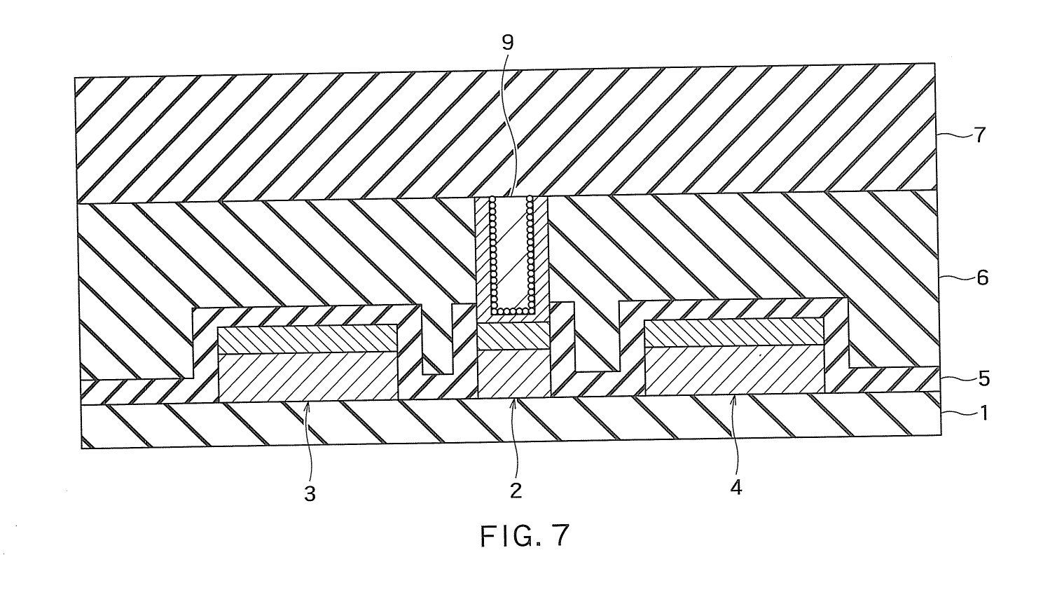

Next, as shown in FIG. 7, the second insulation layer 7 is stacked on the flattened first insulation layer 6. At the step explained above, the first sacrificial layer 9 is formed inside of the first opening 61. Accordingly, when the second insulation layer 7 is stacked, an insulator that constitutes the second insulation layer 7 does not enter the first opening 61. As a result, it is possible to prevent an increase in the electrical resistance of the inner surface of the first opening 61.

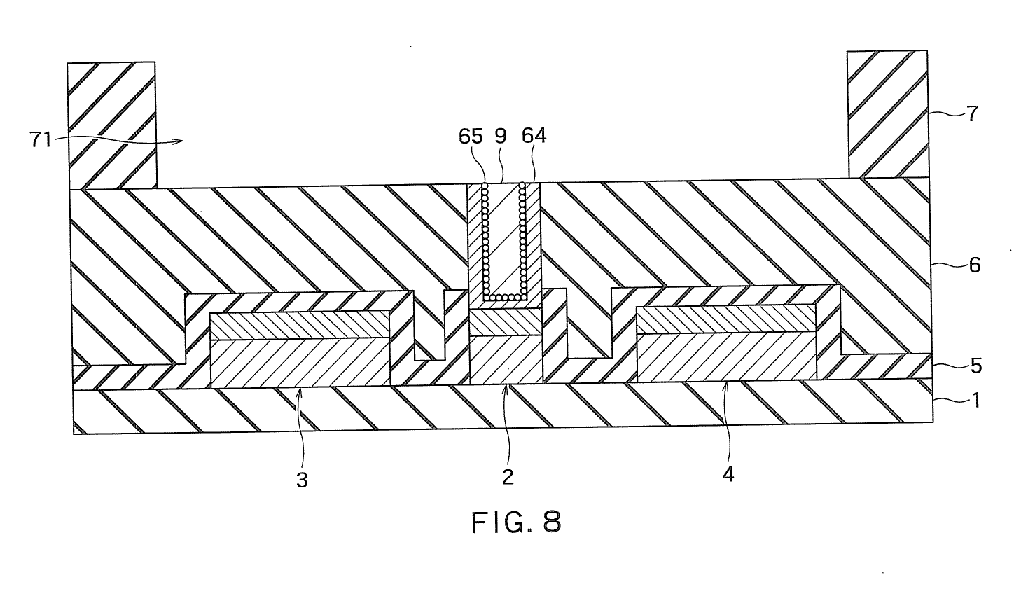

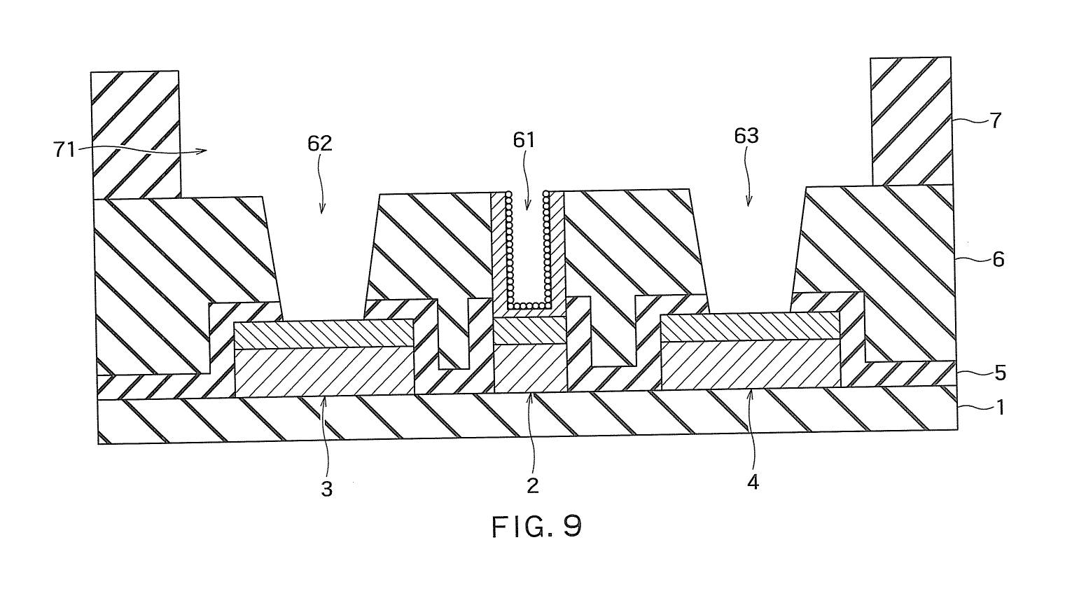

Next, a part of the second insulation layer 7 is removed by lithography and etching. The second insulation layer 7 is removed until the first sacrificial layer 9 is exposed. As a result, as shown in FIG. 8, the trench 71 is formed. Further, a part of the first insulation layer 6 and the water prevention layer 5 is removed via the trench 71 by lithography and etching. As a result, the second opening 62 and the third opening 63 are formed. The first sacrificial layer 9 is removed by ashing. As a result, as shown in FIG. 9, the first opening 61 is opened again.

The first sacrificial layer 9 can be removed by etching together with the second opening 62 and the third opening 63. The ashing mentioned above can be omitted. In this case, the first sacrificial layer 9 is removed at a step subsequent to this step.

Next, a second sacrificial layer 10 is stacked. The second sacrificial layer 10 is stacked so as to fill the first opening 61, the second opening 62, and the third opening 63. The second sacrificial layer 10 is also stacked so as to fill at least a part of the trench 71. Similarly to the first sacrificial layer 9, the second sacrificial layer 10 is stacked assuming that it is removed at a subsequent step. A resist material containing carbon is stacked as the second sacrificial layer 10. For example, the second sacrificial layer 10 can be stacked by spin coating.

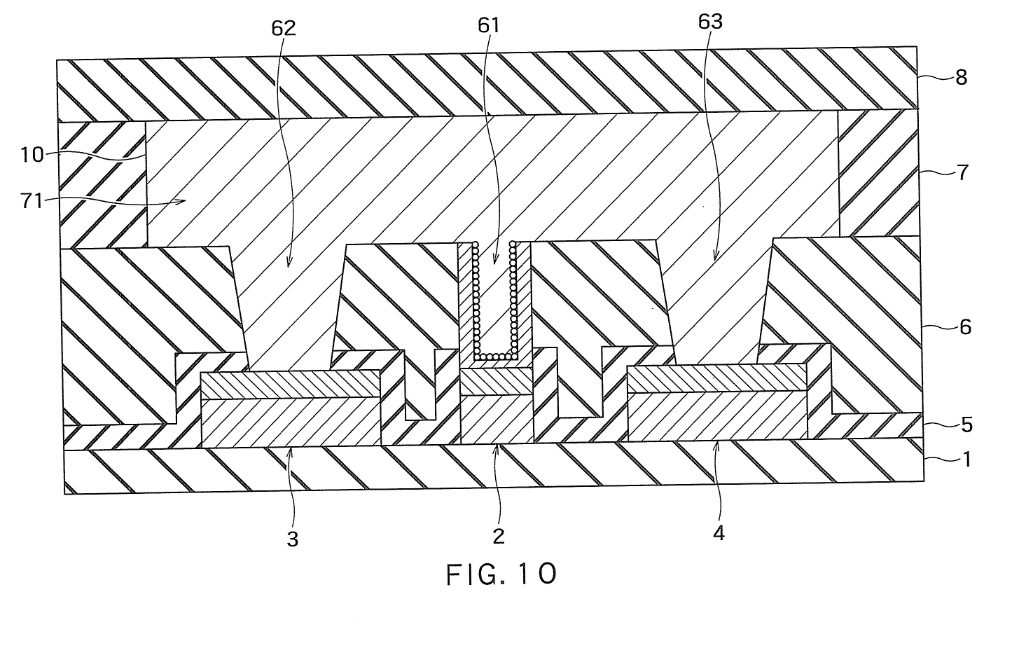

After the second sacrificial layer 10 is stacked, surfaces of the second insulation layer 7 and the second sacrificial layer 10 are flattened by CMP. As shown in FIG. 10, the cover layer 8 is stacked on the flattened second insulation layer 7 and second sacrificial layer 10. In this manner, because the cover layer 8 is stacked while the second sacrificial layer 10 is formed inside of the second insulation layer 7, the cover layer 8 being flat can be stacked.

After the cover layer 8 is stacked, a part of the cover layer 8 is removed by lithography and etching, thereby forming the first through hole 81 and the second through hole 82. Ashing is then performed on the second sacrificial layer 10 via the first through hole 81 and the second through hole 82. As a result, as shown in

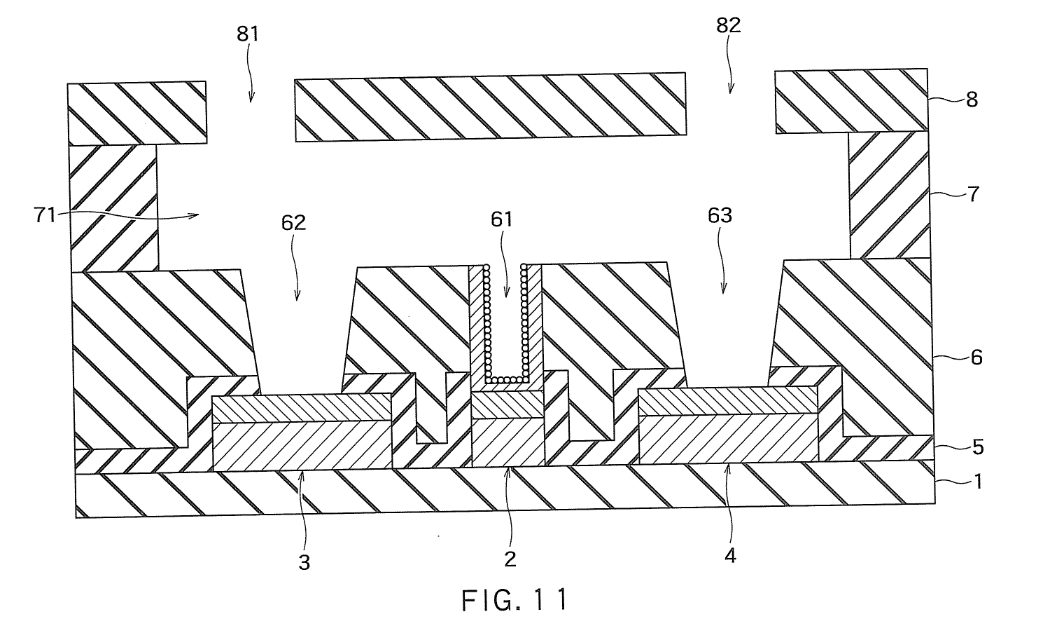

FIG. 11, the second sacrificial layer 10 is removed and a flow path is formed. When the first sacrificial layer 9 is not removed at the step explained with reference to FIG. 9, the first sacrificial layer 9 can be removed by ashing at this step.

Further, the CNT electrode 66 is formed by CVD. More specifically, a carbon source such as methane and acetylene is supplied from the first through hole 81 and the second through hole 82 to the flow path formed by ashing explained above. As a result, a CNT can be selectively grown from the inside of the first opening 61 having the catalyst layer 65 formed therein. The CNT is then grown until protruding from the surface of the first insulation layer 6, thereby forming the CNT electrode 66. By adjusting the CVD temperature, the carbon source, the time, and the like, the configuration of a CNT to be grown and the length of the CNT electrode 66 can be adjusted. For example, by adjusting the length of the CNT electrode 66, the CNT electrode 66 can be formed so that a part thereof protruding from the first insulation layer 6 spreads in a fan shape. The surface area contacting a detection target material is thus increased to improve the detection sensitivity of a biosensor.

As explained above, according to the manufacturing method of a biosensor of the present embodiment, the first electrode 2, the second electrode 3 (the counter electrode), and the third electrode 4 (the reference electrode) can be formed simultaneously. That is, processes of forming the respective electrodes are unnecessary.

Accordingly, the manufacturing process and the configuration of a biosensor can be simplified. Even after the cover layer 8 is formed, the carbon nanotube electrode 66 (the working electrode) can be easily formed on the first electrode 2 by CVD.

According to the present embodiment, a biosensor can be formed by an existing thin-film processing process. Therefore, a biosensor can be formed easily at low cost. Moreover, the biosensor can be downsized.

Because of the high detection sensitivity and the low electrical resistivity of a carbon nanotube, it is possible to detect a material with high sensitivity and high selectivity and reduce the time for inspection.

According to the present embodiment, a plurality of biosensors can be formed simultaneously on the substrate 1. Therefore, a manufacturing time per biosensor can be reduced and the unit price of manufacturing can be also reduced.

When a biosensor does not include the second insulation layer 7 and the cover layer 8, a manufacturing process can be further simplified. Specifically, after the catalyst layer 65 is formed inside of the first opening 61 in the first insulation layer 6, a part of the catalyst layer 65 and the underlayer 64 is removed by

CMP, so that the surface of the first insulation layer 6 is exposed. Next, the second opening 62 and the third opening 63 are formed by lithography and etching. At this time, a resist material stacked on the first insulation layer 6 for forming an etching mask enters inside of the first opening 61. Such a resist material can be removed by ashing after the second opening 62 and the third opening 63 are formed. After the resist material is removed, the CNT electrode 66 is formed by CVD. With such a configuration, it is possible to further simplify the manufacturing process and the configuration of a biosensor.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A biosensor comprising:
a first electrode, a second electrode, and a third electrode formed on a substrate,
the first electrode, the second electrode, and the third electrode including a same layer;
a first insulation layer formed on the substrate so as to cover the first electrode, the second electrode, and the third electrode, the first insulation layer comprising a first opening formed to expose at least a part of a surface of the first electrode, a second opening formed to expose at least a part of a surface of the second electrode, and a third opening formed to expose at least a part of a surface of the third electrode; and
a carbon nanotube electrode formed inside of the first opening, a part of the carbon nanotube protruding from a surface of the first insulation layer.

2. The biosensor of claim 1, wherein the first electrode, the second electrode, and the third electrode are formed of a same material.

3. The biosensor of claim 2, wherein
the first electrode, the second electrode, and the third electrode comprise
a base electrode formed on the substrate, and
a surface electrode formed of a material different from that of the base electrode on the base electrode.

4. The biosensor of claim 1, further comprising a water prevention layer between the substrate and the first insulation layer in order to prevent water from entering the substrate.

5. The biosensor of claim 1, further comprising a second insulation layer formed on a part of the first insulation layer.

6. The biosensor of claim 5, further comprising a cover layer formed on the second insulation layer so as to cover the first insulation layer, wherein
the cover layer comprises a first through hole and a second through hole.

7. The biosensor of claim 1, wherein the carbon nanotube electrode comprises a plurality of carbon nanotubes and a part of the carbon nanotube electrode is formed so as to spread from a surface of the first insulation layer in a fan shape.

8. The biosensor of claim 6, further comprising:
a flow path in which a fluid flows through the first through hole, wherein
the fluid contacts the second electrode, the third electrode, and the carbon nanotube electrode in the flow path, and
the fluid flows out of the flow path through the second through hole.

9. The biosensor of claim 1, wherein
the substrate comprises an electronic circuit, and
the electronic circuit is connected to the first electrode, the second electrode, and the third electrode, respectively.

10. A manufacturing method of a biosensor comprising:
forming a first electrode, a second electrode, and a third electrode on a substrate, the first electrode, the second electrode, and the third electrode including a same layer;
forming a first insulation layer so as to cover the first electrode, the second electrode, and the third electrode, the first insulation layer comprising a first opening formed to expose at least a part of a surface of the first electrode, a second opening formed to expose at least a part of a surface of the second electrode, and a third opening formed to expose at least a part of a surface of the third electrode on the substrate; and
forming a carbon nanotube electrode inside of the first opening, a part of the carbon nanotube electrode protruding from a surface of the first insulation layer.

11. The method of claim 10, wherein
the formation of the first electrode, the second electrode, and the third electrode is executed simultaneously and comprises:
stacking a metal material layer on the substrate; and
etching a part of the metal material layer.

12. The method of claim 10, wherein
the formation of the first insulation layer is comprises:
after the first electrode, the second electrode, and the third electrode are formed, stacking the first insulation layer on the substrate,
forming the first opening by etching;
forming a catalyst layer for forming the carbon nanotube electrode inside of the first opening; and
forming the second opening and the third opening.

13. The method of claim 10, further comprising, after the first opening is formed, forming an underlayer formed of a promoter metal facilitating growth of a carbon nanotube from the catalyst layer inside of the first opening, wherein
the catalyst layer is formed inside of the underlayer.

14. The method of claim 10, further comprising, after the first electrode, the second electrode, and the third electrode are formed, forming a water prevention layer on the substrate in order to prevent water from entering the substrate, wherein
the first insulation layer is formed on the water prevention layer.

15. The method of claim 10, further comprising:
forming a second insulation layer on a part of the first insulation layer;
forming a cover layer on the second insulation layer to cover the first insulation layer, the cover layer comprising a first through hole and a second through hole; and
forming a flow path in which a fluid flows through the first through hole, the fluid contacting the second electrode, the third electrode, and the carbon nanotube electrode in the flow path, and the fluid flows out of the flow path through the second through hole.

16. The method of claim 15, further comprising:
after the first opening is formed, forming a first sacrificial layer filling inside of the first opening;
stacking the second insulation layer on the first insulation layer and the first sacrificial layer;
forming a trench located above the first electrode, the second electrode, and the third electrode by etching the second insulation layer; and
forming the second opening and the third opening by etching the first insulation layer via the trench.

17. The method of claim 16, wherein the first sacrificial layer is removed by etching when the second opening and the third opening are formed.

18. The manufacturing method of a biosensor of claim 15, wherein
the formation of the cover layer comprises:
after the second opening and the third opening are formed, forming a second sacrificial layer inside of the second insulation layer;
stacking a cover layer on the second insulation layer and the second sacrificial layer; and
forming the first through hole and the second through hole by etching the cover layer on the second sacrificial layer.

19. The method of claim 18, wherein
the first sacrificial layer and the second sacrificial layer are formed of a resist material, and
the first sacrificial layer is removed simultaneously with the second sacrificial layer.

20. The method of claim 15, wherein
the formation of the carbon nanotube electrode comprises:
after the flow path is formed, supplying a carbon source via the first through hole and the second through hole; and
growing a carbon nanotube from inside of the first opening.
